(19) United States
(12) Patent Application Publication
(10) Pub. No.: US 2010/0308340 A1
(43) Pub. Date: Dec. 9, 2010

(54) SEMICONDUCTOR DEVICE HAVING A BURIED CHANNEL

(75) Inventors: Vinayak Tilak, Niskayuna, NY (US); Peter Almern Losee, Clifton Park, NY (US)

Correspondence Address: GENERAL ELECTRIC COMPANY;GLOBAL RESEARCH, ONE RESEARCH CIRCLE, BLDG. K1-3A59, NISKAYUNA, NY, 12309, US

(73) Assignee: GENERAL ELECTRIC COMPANY, Schenectady, NY (US)

(21) Appl. No.: 12/478,106

(22) Filed: Jun. 4, 2009

(51) Int. Cl. H01L 29/24

(52) U.S. Cl. 257/77; 257/213; 257/E29.104

(57) ABSTRACT

Provided is a device that includes a semiconductor body having a surface. Source and drain regions with effective dopant populations of a first polarity can be disposed adjacent to the surface and spaced apart from one another. A channel region with an effective dopant population of the first polarity can extend between the source and drain regions while being spaced apart from the surface. A gate region with an effective dopant population of a second polarity and first effective dopant density can extend between the source and drain regions and be disposed between the channel region and the surface. A gate contact region can be disposed between the source and drain regions and adjacent to the surface. The gate contact region can have an effective dopant population of the second polarity and a second effective dopant density greater than the first effective dopant density.

### BACKGROUND

Embodiments of the present invention relate to semiconductor devices, and more particularly, to semiconductor devices including buried channels.

There are a variety of applications for semiconductor devices operating at elevated temperatures or in harsh environments. Examples include distributed control modules for aircraft engines, sensors for operating in chemically reactive environments, and components in combustion control systems. However, at elevated temperatures, the performance of common silicon-based semiconductor devices tends to deteriorate. One reason for this deterioration is an increase in the rate of thermal generation of intrinsic charge carriers, which generation can obscure the switch-controlled operation of the device.

Silicon carbide (SiC) has been proposed as a semiconductor material that might be more suitable for use in devices intended for high temperature operation. One reason for proposing SiC for such applications is that the electronic bandgap of SiC is significantly greater than that for silicon. Further, SiC exhibits relatively high thermal conductivity, which allows for efficient cooling of SiC-based devices. Additionally, SiC is relatively inert, and SiC devices may tend to resist corrosion or other deterioration that may be expected for other types of devices at elevated temperatures. However, despite these apparent advantages, SiC devices are presently only utilized in a limited number of applications, and typical SiC device performance is often found to be less than theoretically predicted performance of such devices.

### SUMMARY

In one aspect, a device is provided that includes a semiconductor body, such as a silicon carbide body. The semiconductor body can have a surface, such as a continuous polished surface or otherwise generally planar and/or with a curvature that is substantially continuous, and can include a source region, a drain region, a channel region, a gate region, and a gate contact region. The source region can have an effective dopant population of a first polarity and can be disposed adjacent to the surface of the semiconductor body. The drain region can have an effective dopant population of the first polarity and can be disposed adjacent to the surface and spaced apart from the source region. The channel region can have an effective dopant population of the first polarity and can extend between the source and drain regions while being spaced apart from the surface. The gate region can have an effective dopant population of a second polarity and first effective dopant density, and can extend between the source and drain regions and be disposed between the channel region and the surface. The gate contact region can be disposed between the source and drain regions and adjacent to the surface (e.g., by being incorporated within the gate region). The gate contact region can have an effective dopant population of the second polarity and a second effective dopant density greater than the first effective dopant density (e.g., at least 100 times greater).

In one embodiment, the source, drain, and channel regions include n-type doped silicon carbide, and the gate and gate contact regions include p-type doped silicon carbide. The channel region can have an effective channel dopant density in the range of about 5×10¹⁶ cm⁻³ to about 5×10¹⁷ cm⁻³, the first effective dopant density in the gate region can be in the range of about 5×10¹⁷ cm⁻³ to about 5×10¹⁸ cm⁻³, and the second effective dopant density in the gate contact region can be in the range of about 5×10¹⁹ cm⁻³ to about 5×10²⁰ cm⁻³. The surface can. The surface may be at least partly coated with polyimide.

The gate contact region may be configured to selectively receive charge. For example, an electrode may be included and configured so as to make ohmic contact with the gate contact region. The gate contact region can have a transverse perimeter area, and the electrode can be spaced apart from the transverse perimeter area. The gate contact region may also be spaced apart from each of the source and drain regions.

### BRIEF DESCRIPTION OF THE DRAWINGS

Having thus described various embodiments in general terms, reference will now be made to the accompanying drawings, which are not necessarily drawn to scale, and wherein:

FIG. 1 is a schematic cross-sectional view of a junction field effect transistor (JFET) configured in accordance with an example embodiment;

FIGS. 2A and 2B are schematic cross-sectional views of the JFET of FIG. 1, the views schematically representing the operation of the JFET;

FIGS. 3-16 are schematic cross-sectional views representing an example process flow for fabricating the JFET of FIG. 1; and

FIG. 17 is a plot of dopant concentration as a function of depth for the channel, gate, and gate contact layers of a JFET fabricated in accordance with an example embodiment.

### DETAILED DESCRIPTION

Certain embodiments now will be described more fully hereinafter with reference to the accompanying drawings, in which some, but not all embodiments of the subject invention are shown. Indeed, the subject invention may be embodied in many different forms and should not be construed as limited to the embodiments set forth herein; rather, these embodiments are provided so that this disclosure will satisfy applicable legal requirements. Like numbers refer to like elements throughout.

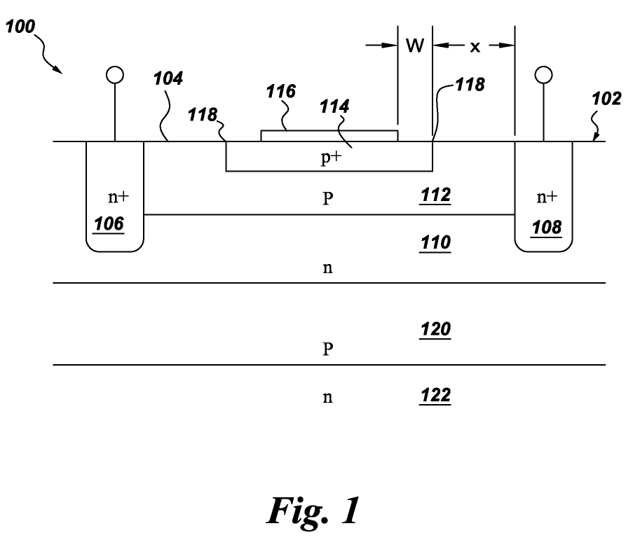

Referring to FIG. 1, therein is shown a schematic cross sectional view of a device, such as a junction field effect transistor (JFET) 100, configured in accordance with an example embodiment. The JFET 100 includes a semiconductor body 102, which may be composed of one or more semiconducting materials (e.g., silicon, silicon carbide (SiC), silicon germanium, germanium, gallium arsenide, gallium nitride, indium gallium arsenide, etc.). The semiconductor body 102 can have a surface 104 and can include a source region 106, a drain region 108, a channel region 110, a gate region 112, and a gate contact region 114, each of which will be described in more detail below.

The semiconductor body 102 may be part of a semiconductor chip or wafer, and the surface 104 may be an as-grown surface or a continuous polished surface (over the span of the JFET 100) prepared, for example, through standard chemical-mechanical polishing techniques. In some embodiments, the surface 104 may be generally planar and/or have a curvature that is substantially continuous, at least over the span of the JFET 100. The semiconductor body 102 may have a thickness of, for example, 500 μm or more.

Each of the source region 106 and the drain region 108 may be disposed adjacent to the surface 104, and may have an “effective dopant population” of a first polarity. The “effective dopant population” represents the dopant population that can effectively contribute to the conductivity of the doped region. For example, a spatial volume may include a concentration of n-type dopant of 6×10¹⁰ ions/cm³, and the same spatial volume may include a concentration of p-type dopant of 4×10¹⁰ ions/cm³. Because the holes produced by the p-type dopant tend to combine with a similar number of electrons provided by the n-type dopant, the density of the “effective dopant population” (i.e., the “effective dopant density”) is 2×10¹⁰ ions/cm³, and the “effective dopant population is n-type in polarity. As such, the spatial volume would, in the absence of other effects (such as, for example, being disposed adjacent to a neighboring p-type region) have electrons as the majority carriers.

The source and drain regions 106, 108 may, for example, be configured to be n-type regions (i.e., to have an effective dopant population with n-type polarity), as shown in FIG. 1. The source and drain regions 106, 108 may be spaced apart from one another, with the channel region 110 extending between the two. The channel region 110 may be disposed within the semiconductor body 102 and away from the surface 104 (and may therefore be referred to as a “buried” channel region). The thickness of the channel region 110 may be, for example, about 150 nm. As with the source and drain regions 106, 108, the channel region 110 can have an effective dopant population of the first polarity; in the example of FIG. 1, all of the source, drain, and channel regions are n-type. The effective dopant concentration in the source and drain regions 106, 108 may be higher than that in the channel region 110, as indicated in FIG. 1 by the n and n⁺ denominations. For example, in one embodiment, the effective dopant concentration in the channel region 110 may be in the range of approximately 10¹⁶-10²¹ cm⁻³, while the concentration of majority carriers in the source and drain regions 106, 108 may be several orders of magnitude higher than that in the channel region. It should be understood that dopant concentrations and effective dopant concentrations may vary spatially throughout a given volume, either randomly or by increasing or decreasing in a given direction.

The gate region 112 can also extend between the source and drain regions 106, 108 so as to be disposed between the channel region 110 and the surface 104. The thickness of the gate region 112 may be, for example, about 150 nm, such that the total aggregate thickness of the gate region and the channel region 110 is less than about 400 nm. The gate region 112 can have an effective dopant population of a second polarity; in the example of FIG. 1, the gate region 112 would be configured to be p-type. The gate contact region 114 can be disposed between the source and drain regions 106, 108 and adjacent to the surface 104, and may have a thickness, for example, of about 50 nm. The gate contact region 114 may extend between the source and drain regions 106, 108 or may be spaced apart from each of the source and drain regions, as depicted in FIG. 1, by a distance x that may be, for example, at least 750 nm. In some embodiments, the gate contact region 114 may be incorporated partly or wholly within the gate region 112, such that the gate contact region is at least partly contained within a volume generally defined by the gate region (see FIG. 1). As with the gate region 112, the gate contact region 114 can have an effective dopant population of the second polarity (e.g., p-type in FIG. 1).

The gate region 112 and gate contact region 114 can be configured such that the gate region has a first effective dopant density and the gate contact region has a second effective dopant density that is greater than the first density (represented in FIG. 1 by the p and p⁺ symbols). For example, the gate region 112 may have an effective p-type dopant density (and, similarly, a nominal hole density when the dopant is fully ionized) on the order of approximately 10¹⁶-10²¹ cm⁻³, while the gate contact region 114 may have an effective p-type dopant density that is roughly two or more orders of magnitude higher. It will be understood that the noted effective dopant concentrations are average concentrations for the regions of interest, and will generally correspond to majority carrier concentrations (although actual charge carrier concentrations will vary, for example, in depletion regions that may develop at of p-n junctions).

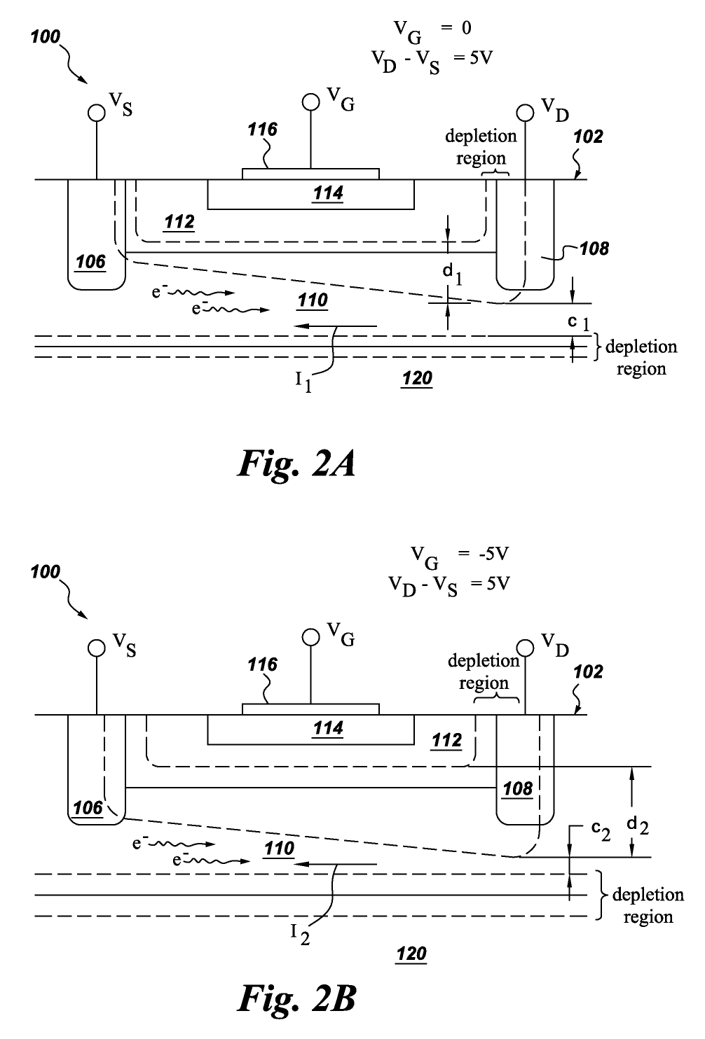

The gate contact region 114 can be configured to selectively receive charge. For example, a gate electrode 116 can be disposed in electrical contact (say, ohmic contact) with the gate contact region 114 to allow a gate voltage V_{G} (FIG. 2) to be applied at the gate contact region. (In practice, the gate electrode 116 is often biased with respect to the source region 106, and the gate voltage V_{G} is denoted instead as V_{GS}. However, whether or not the gate electrode 116 is biased with respect to the source region 106, it should be understood that the gate electrode and source will have a common reference.) In some embodiments, the electrode 116 may contact the gate contact region 114 such that the electrode is spaced apart from a transverse perimeter area 118 of the gate contact region (e.g., in FIG. 1, the perimeter area of the gate contact region as seen at the surface 104). The gate electrode 116 may be spaced from the transverse perimeter area 118 by an amount d that is, for example, at least 250 nm.

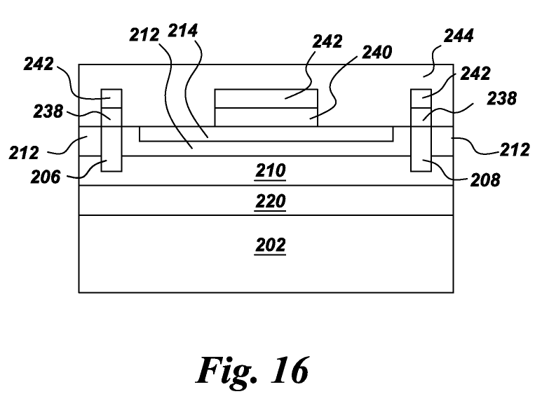

The semiconductor body 102 may also include a channel barrier region 120 disposed below the channel region 110 (“below” in this case being with respect to the surface 104, as shown in FIG. 1). The channel barrier region 120 may have an effective dopant population of the second polarity (i.e., holes in FIG. 1, making the channel barrier region p-type) and a thickness, for example, of about 3 μm. There may also be a substrate region 122 below the channel barrier region 120 that extends through the remaining thickness of the semiconductor body 102 and is configured to have an effective dopant population of the first polarity. Further, in some embodiments, the surface 104 may be covered by a passivation layer or protective coating material (see FIG. 16, discussed below), such as polyimide and/or nitrided silicon dioxide. Any type of passivation layer may be utilized at the surface 104 that does not result in hot electron trapping at the interface with the passivation layer.

Referring to FIGS. 2A-B, therein the operation of the JFET 100 of FIG. 1 is schematically illustrated. A source voltage V_{S} and a drain voltage V_{D} can be applied, respectively, to the source and drain regions 106, 108, such that a potential difference V_{D}−V_{S} exists across the source and drain regions. This potential difference causes the majority charge carriers (electrons) in the source, drain, and channel regions 106, 108, 110 to drift along the path defined by those regions. For example, for a potential difference V_{D}−V_{S}=5 V, the electrons would move to the drain region 108 from the source region 106 and the current I₁ would therefore flow in the opposite direction, as shown in FIG. 2A. At the various points where p-type and n-type material comes in contact (“p-n junctions”) throughout the JFET 100, depletion regions will naturally develop (for example, having a thickness d₁). However, the channel region 110 still includes ample volume within which charge carriers are plentiful and conduction is possible. For example, if the conductive portion of the channel region 110 is represented by the thickness c₁, then for the conditions depicted in FIG. 2A, c₁ is of sufficient thickness to allow significant conduction.

As mentioned above, in FIG. 2A, the gate voltage V_{G} of zero has been applied to the gate electrode 116. In FIG. 2B, V_{G} has been reduced to −5 V, while the potential difference (V_{D}−V_{S}) across the source and drain regions 106, 108 has been maintained at 5 V. The potential difference V_{D}−V_{S} continues to provide a driving force for electron drift through the channel region 110. However, the decrease in the gate voltage V_{G} to −5 V results in an increase in the size of the depletion region between the channel region 110 and the gate region 112 (and possibly in other areas as well). If the thickness of the depletion region under the conditions depicted in FIG. 2B is represented by d₂, then d₂>d₁. Correspondingly, the conductive volume (represented by the thickness c₂ in FIG. 2B) of the channel region 110 is reduced (i.e., c₂<c₁), and the current I₂ through the device 100, for a given current driving force V_{D}−V_{S}, is similarly reduced (i.e., I₂<I₁).

As negative charge is applied to the gate electrode 116, some charge carriers (electrons in this case) may drift from the gate electrode toward the gate region 112, and possibly further towards the source region 106 due to the potential difference with respect to the gate electrode. Given the relatively high concentration of holes in the gate contact region 114, these electrons may tend to combine with holes in the gate contact region, such that little current flows between the gate electrode 116 and the gate region 112.

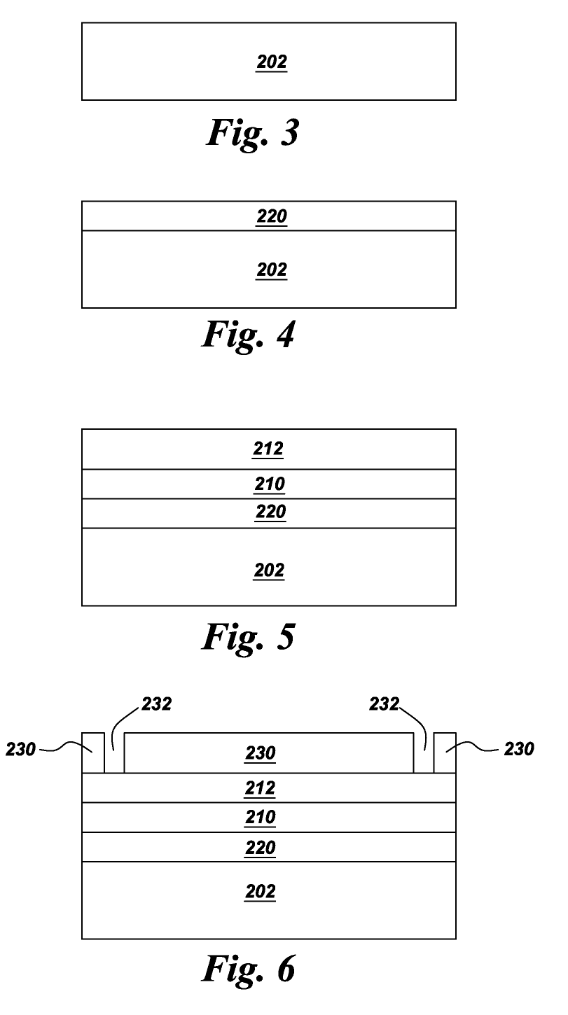

Referring to FIGS. 3-16, therein are schematically demonstrated a process for fabricating a device, such as the JFET 100 (FIG. 1) that is configured in accordance with an example embodiment. In this example, the JFET 100 includes SiC as the base material, and the process starts with a SiC substrate 202 that is uniformly doped n-type (FIG. 3). For example, the substrate 202 may be grown so as to include therein nitrogen or phosphorous, both of which are common n-type dopants for SiC. A channel barrier layer 220 of p-type SiC (e.g., with thickness of about 3 μm) can then be epitaxially grown onto the substrate 202 (FIG. 4). The channel barrier layer 220 could be grown so as to include atoms of, say, one of boron or aluminum, either of which is capable of acting as a p-type dopant for SiC.

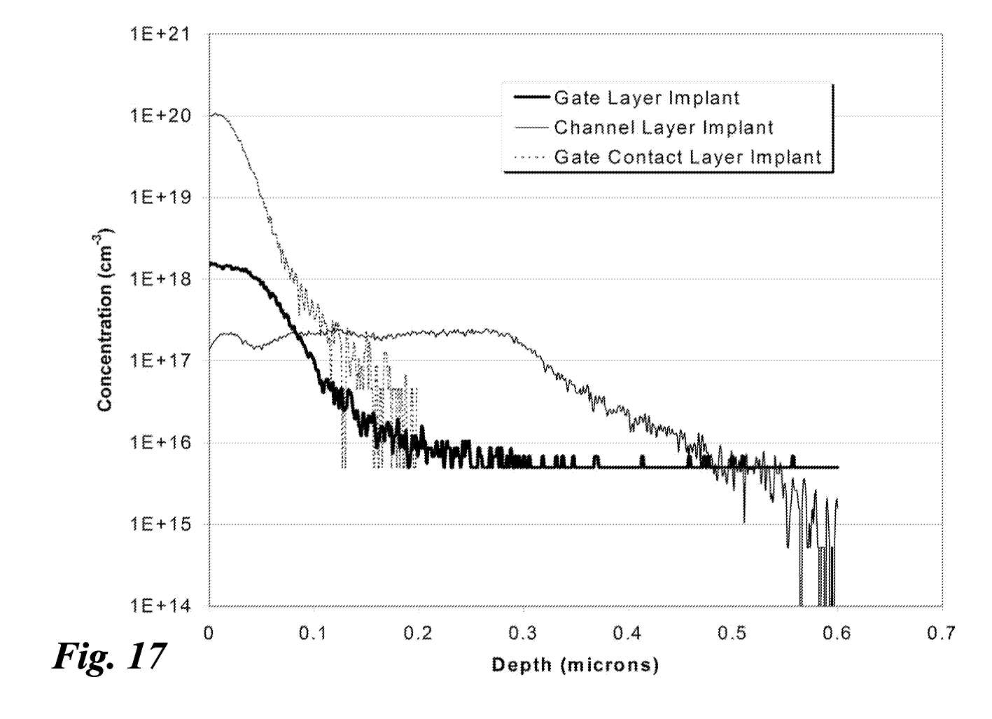

Next, dopants are implanted, e.g., via ion implantation, into the channel barrier layer 220 to create a stacked n-type channel region layer 210 and a p-type gate region layer 212 (FIG. 5). Each of the channel and gate region layers 210, 212 can be, for example, about 150 nm thick, such that the total thickness of the channel and gate region layers is less than about 400 nm. In one embodiment, the doping profile for which is represented by FIG. 17, all of the top 300 nm can be implanted with an n-type dopant at a first dopant concentration (say, in the range of 5×10¹⁶ cm⁻³ to 5×10¹⁷ cm⁻³, and more specifically, about 2×10¹⁷ cm⁻³), and then the top 150 nm can be implanted with a p-type dopant at a second, higher concentration (say, in the range of 5×10¹⁷ cm⁻³ to 1×10²⁰ cm⁻³, and more specifically, about 2×10¹⁸ cm⁻³). Such an implantation process (and associated anneal, which is discussed below) employing the dopant concentration profiles shown in FIG. 17 would produce a layered n-type and p-type channel and gate region layers 210, 212, shown in FIG. 5, with the channel and gate region layers having effective dopant (and, nominally, charge carrier for fully ionized dopants) concentrations of 2×10¹⁷ cm⁻³ and 1.8×10¹⁸ cm⁻³, respectively. In another embodiment, the ion implantation energy can be varied such that p-type dopants are implanted only in the top 250 nm of the substrate 202 and the n-type dopants are implanted only in the underlying 250 nm.

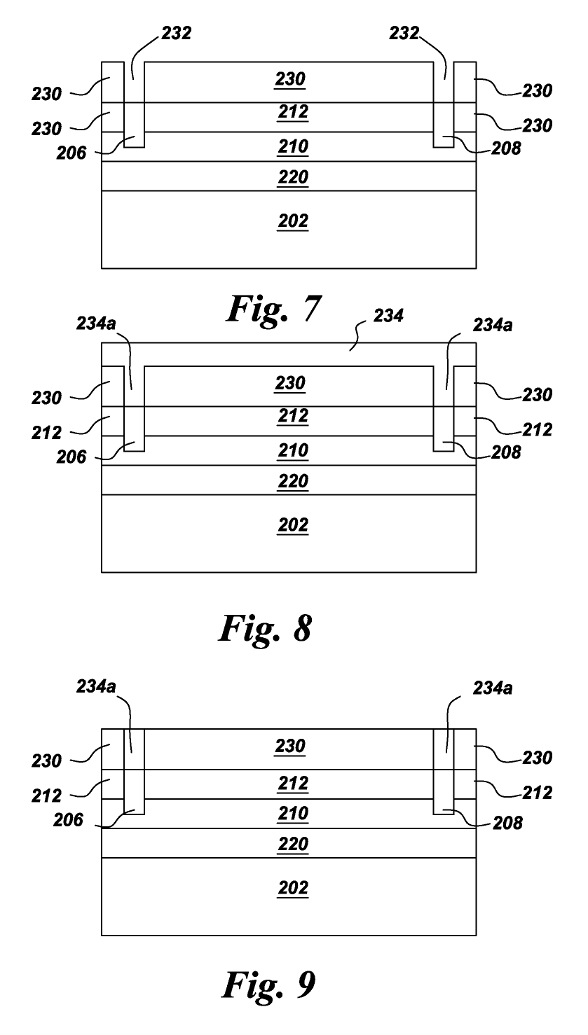

A silicon dioxide (“oxide”) layer 230 can then be grown and/or deposited onto the gate region layer 212 and subsequently patterned, e.g., using standard photolithographic techniques (FIG. 6). Following patterning, the oxide layer 230 defines several windows 232 therethrough. N-type dopant can then be implanted through the windows 232 and into the underlying SiC substrate 202, thereby forming source and drain regions 206, 208 (FIG. 7). The ion implantation can be configured to produce, for example, a dopant density in the range of 5×10¹⁹ cm⁻³ to 5×10²⁰ cm⁻³, and more specifically, of about 2×10²⁰ cm⁻³, extending about 350 nm into the substrate 202. Following ion implantation, a layer of silicon nitride 234 (or another compatible material) can be deposited over the oxide layer 230 (FIG. 8). Portions 234a of the silicon nitride layer 234 can act to fill in the windows that had previously been patterned into the oxide layer 230. The substrate 202 can then be etched and/or polished in order to remove the silicon nitride layer 234 except for the portions 234a inside the windows 232, thereby “planarizing” the substrate (FIG. 9).

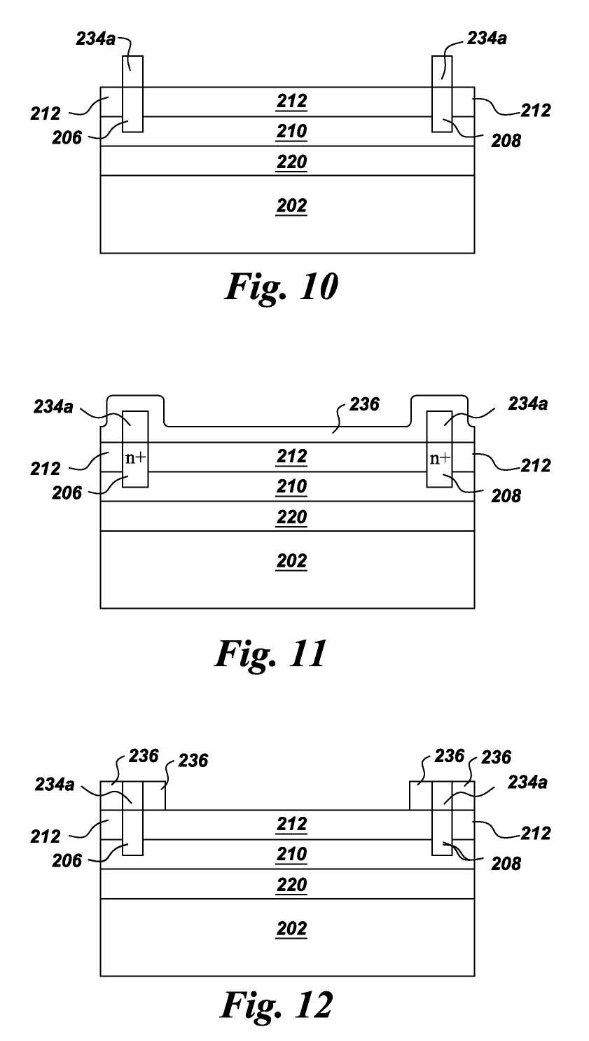

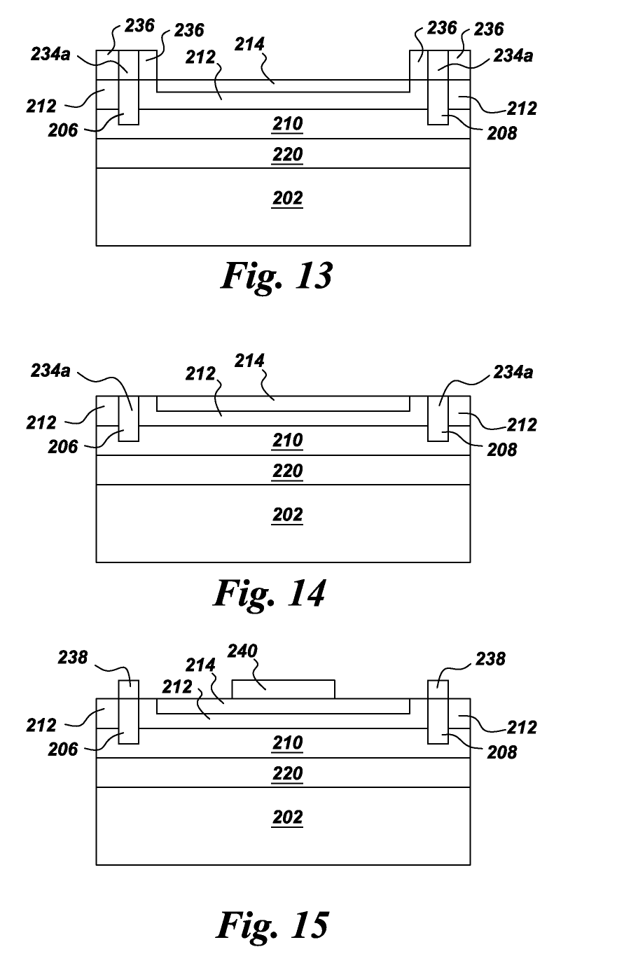

Once the substrate 202 has been planarized, all of the oxide layer 230 can be removed through wet or dry etching, leaving only the portions of the silicon nitride layer 234a that were disposed in the windows of the oxide layer (FIG. 10). A thin (750 nm) layer of silicon dioxide 236 can then be deposited over both the substrate 202 and the silicon nitride portions 234a (FIG. 11). Subsequently, a blanket etch of the oxide layer 236 can be performed, which results in removal of the oxide layer except for portions adjacent to the silicon nitride portions 234a (FIG. 12). Ion implantation can then be carried out in order to create a gate contact layer 214 that includes p-type dopants at a concentration, say, in the range of 5×10¹⁹ cm⁻³ to 5×10²⁰ cm⁻³, and more specifically, of about 2×10²⁰ cm⁻³, extending about 50 nm into the substrate 202 (FIGS. 13 and 17). It is noted that the remaining portions of the oxide layer 236 tend to inhibit implantation in the areas s thereunder.

Once the ion implantation is complete, wet and/or dry etching can be performed to remove the previously remaining oxide layer 236 and silicon nitride portions 234a (FIG. 14). The substrate 202 can then be annealed, for example, at about 1875 K for anywhere from 30 minutes to 10 hours. This anneal acts to activate all of the previously implanted dopants. Metal 238, 240 can then be deposited over the source, drain, and gate contact layers 206, 208, 214, for example, via physical or chemical vapor deposition or plating processes coupled with standard photolithographic techniques (FIG. 15). The metal 238 over the source and drain layers 206, 208 may be the same as the metal 240 over the gate contact layer 214, or these metals may be different and possibly applied in separate processes. In one embodiment, the metal 238, 240 is nickel that is applied via sputtering.

Following metallization, the substrate 202 can be annealed, for example, at about 1320 K for one minute in a nitrogen or forming gas environment. This anneal serves to facilitate a reaction between the metal 238, 240 and the underlying substrate 202, thereby ensuring an ohmic contact between the two. Following anneal, further metal(s) 242 can be applied to the existing metal 238, 240 in order to obtain the desired surface characteristics (say, good solderability) and an upper surface of the substrate can be passivated with a protective coating 244, such as polyimide (FIG. 16).

It has been observed by the present Applicants that surface effects can have a significant influence on semiconductor device performance. For example, surface states can lead to unintended current paths through devices. Such surface states may be attributable to one or more of the presence of the surface itself, surface-related crystal defects, and the presence of impurities at the surface. Further, in the case of silicon-based devices, oxides at the surface often provide surface states that are especially detrimental to device performance. Example embodiments may alleviate some of these surface related issues by providing devices for which (a) the presence of an oxide layer at the surface of a device is unnecessary and/or (b) the channel through which a device conducts is “buried,” that is, spaced apart from the surface. Further, some embodiments may be provided without the use of surface etching that may result in surface defects and contamination.

As charge is applied to the gate electrode 116, there may be a tendency for current to flow into or out of the gate region 112 (the direction of current flow depending on the polarity of charge carriers and gate voltage V_{G}). This “leakage current” may increase power consumption of the device. However, this tendency may be inhibited for devices configured in accordance with some example embodiments. For example, for the device 100 of FIGS. 2A-B, as negative charge is applied to the gate electrode 116, any electrons that move from the gate electrode towards the gate region 212 will quickly combine with respective holes in the gate contact region 214, which gate contact region is heavily doped p-type.

Many modifications and other embodiments of the inventions set forth herein will come to mind to one skilled in the art to which these inventions pertain having the benefit of the teachings presented in the foregoing descriptions and the associated drawings. For example, the device embodiments described above are configured such that the devices would tend to conduct until the application of a gate voltage sufficient to prevent conduction. Specifically, referring to FIGS. 2A and 2B, during operation of the JFET 100, the channel region 110 allows the passage therethrough of current I₁ when a bias exists between the source region 106 and the drain region 108 and no voltage is applied to the gate electrode 116, and the current is reduced to a lower level I₂ when the gate voltage is made increasingly negative. Such a device is referred to as a “normally on” device. However, in other embodiments, the JFET 100 may also be configured to operate as a “normally off” device. For example, by sufficiently reducing the thickness and/or doping level of the channel region 110, the depletion regions formed at the respective junctions between the channel region and the gate region 112 and the channel barrier region 120 can be made to extend completely through the thickness of the channel region. In that case, conduction through the channel region will be significantly inhibited until an appropriate voltage is applied to the gate electrode 116 to counteract the channel region depletion.

Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A device comprising:
a semiconductor body having a surface and including
a source region having an effective dopant population of a first polarity and disposed adjacent to said surface;
a drain region having an effective dopant population of the first polarity and disposed adjacent to said surface and spaced apart from said source region;
a channel region having an effective dopant population of the first polarity and extending between said source and drain regions, said channel region being spaced apart from said surface;
a gate region having an effective dopant population of a second polarity and first effective dopant density, said gate region extending between said source and drain regions and being disposed between said channel region and said surface; and
a gate contact region disposed between said source and drain regions and adjacent to said surface, said gate contact region having an effective dopant population of the second polarity and a second effective dopant density greater than the first effective dopant density.

2. The device of claim 1, wherein said semiconductor body includes silicon carbide.

3. The device of claim 1, wherein said source, drain, and channel regions include n-type doped silicon carbide, and said gate and gate contact regions include p-type doped silicon carbide.

4. The device of claim 1, wherein the second effective dopant density in said gate contact region is at least 100 times greater than the first effective dopant density in said gate region.

5. The device of claim 1, wherein said surface is a continuous polished surface.

6. The device of claim 1, wherein said gate contact region is incorporated within said gate region.

7. The device of claim 1, further comprising an electrode configured to make ohmic contact with said gate contact region.

8. The device of claim 1, wherein said gate contact region is spaced apart from each of said source and drain regions.

9. The device of claim 1, wherein said surface is at least partly coated with polyimide.

10. The device of claim 1, wherein said surface has a curvature that is substantially continuous.

11. The device of claim 1, wherein said surface is generally planar.

12. The device of claim 1, wherein said gate contact region is configured to selectively receive charge.

13. The device of claim 12, wherein said gate contact region has a transverse perimeter area, said device further comprising an electrode in contact with said gate contact region and spaced apart from said transverse perimeter area.

14. The device of claim 1, wherein said channel region has an effective channel dopant density in the range of about 5×10¹⁶ cm⁻³ to about 5×10¹⁷ cm⁻³, the first effective dopant density in said gate region is in the range of about 5×10¹⁷ cm⁻³ to about 5×10¹⁸ cm⁻³, and the second effective dopant density in said gate contact region is in the range of about 5×10¹⁹ cm⁻³ to about 5×10²⁰ cm⁻³.

15. A semiconductor device comprising:
a silicon carbide body having a surface and including
a source region disposed adjacent to said surface and doped to have an effective dopant population of a first polarity;
a drain region disposed adjacent to said surface and spaced apart from said source region, said drain region being doped to have an effective dopant population of the first polarity;
a channel region extending between said source and drain regions and spaced apart from said surface, said channel region being doped to have an effective dopant population of the first polarity;
a gate region doped to have an effective dopant population of a second polarity and first effective dopant density, said gate region extending between said source and drain regions and being disposed between said channel region and said surface; and
a gate contact region disposed between said source and drain regions and adjacent to said surface, said gate contact region being doped to have an effective dopant population of the second polarity and a second effective dopant density greater than the first effective dopant density.

16. The device of claim 15, wherein said source, drain, and channel regions include n-type doped silicon carbide, and said gate and gate contact regions include p-type doped silicon carbide.

17. The device of claim 15, wherein the second effective dopant density in said gate contact region is at least 100 times greater than the first effective dopant density in said gate region.

18. The device of claim 15, wherein said surface is a continuous polished surface.

19. The device of claim 15, wherein said gate contact region is incorporated within said gate region.

20. The device of claim 15, further comprising an electrode configured to make ohmic contact with said gate contact region.

21. The device of claim 15, wherein said gate contact region is spaced apart from each of said source and drain regions.

22. The device of claim 15, wherein said surface is at least partly coated with polyimide.

23. The device of claim 15, wherein said surface has a curvature that is substantially continuous.

24. The device of claim 15, wherein said surface is generally planar.

25. The device of claim 15, wherein said gate contact region is configured to selectively receive charge.

26. The device of claim 25, wherein said gate contact region has a transverse perimeter area, said device further comprising an electrode in contact with said gate contact region and spaced apart from said transverse perimeter area.

27. The device of claim 15, wherein said channel region has an effective channel dopant density in the range of about 5×10¹⁶ cm⁻³ to about 5×10¹⁷ cm⁻³, the first effective dopant density in said gate region is in the range of about 5×10¹⁷ cm⁻³ to about 5×10¹⁸ cm⁻³, and the second effective dopant density in said gate contact region is in the range of about 5×10¹⁹ cm⁻³ to about 5×10²⁰ cm⁻³.
